(19) United States
(12) Patent Application Publication
(10) Pub. No.: US 2025/0146136 A1
(43) Pub. Date: May 8, 2025

(54) GRAPHITE STRUCTURE AND METHOD FOR MANUFACTURING SAME

(71) Applicant: Panasonic Intellectual Property Management Co., Ltd., Osaka (JP)

(72) Inventors: TAKASHI TSURUTA, Osaka (JP); RYOU KUWABARA, Osaka (JP); NAOMI NISHIKI, Kyoto (JP)

(21) Appl. No.: 19/015,789

(22) Filed: Jan. 10, 2025

Related U.S. Application Data
(63) Continuation of application No. PCT/JP2023/022545, filed on Jun. 19, 2023.

(30) Foreign Application Priority Data
Jul. 22, 2022 (JP) 2022-117465

(51) Int. Cl. C23C 28/02; F28F 13/18; H05K 7/20

(52) U.S. Cl. CPC C23C 28/023; F28F 13/18; H05K 7/20445

(57) ABSTRACT

Provided are a graphite plate including at least one or more through-holes passing through the graphite plate in a direction orthogonal to a basal surface of the graphite plate, a coating layer covering an inner peripheral surface of the at least one through-hole and an entire circumference of the graphite plate, the coating layer including a first metal capable of forming a compound with carbon atoms constituting the graphite plate, a porous second metal covering an entire circumference of the coating layer including a region surrounded by the inner peripheral surface of the at least one through-hole, and a third metal covering an entire circumference of the porous second metal, the graphite plate and the porous second metal being bonded to each other with the coating layer interposed the graphite plate and the porous second metal, and the third metal being bonded to the porous second metal.

### TECHNICAL FIELD

The present disclosure relates to a graphite structure and a method for manufacturing the same. More specifically, the present invention relates to a graphite structure used for a semiconductor device, an in-vehicle device, an electronic device, and the like. The graphite structure efficiently diffuses and radiates heat to eliminate defects due to heat generation of a device, and maintain and improve functions of the device.

### BACKGROUND ART

As high-speed communication standards have been spread in recent years, devices such as a semiconductor device, an in-vehicle device, and an electronic device have high output that causes a part of each of the devices or the periphery thereof to have a high temperature. To avoid functional degradation or stop of the devices caused by this high temperature, propagation and dissipation of heat caused by the high temperature have been conventionally devised in which a copper heat spreader or an aluminum heat dissipation fin is used for the propagation and dissipation of the heat to a substrate and a housing. As a material for heat transfer and heat dissipation as described above, a material having high thermal conductivity such as a metal or a carbide is used.

In particular, crystalline graphite has high thermal conductivity, and thus is expected to be utilized as a thermal diffusion material or a thermal transport material. However, the crystalline graphite is known to be difficult to be utilized alone due to its strong anisotropy in a plane direction and a thickness direction. For example, thermal conduction and strength in the plane direction are several tens of times or more different from those in the thickness direction. To be utilized as the thermal diffusion material or the thermal transport material, the crystalline graphite is required to form a composite with a metal having a high thermal conductivity without impairing the thermal conduction of the crystalline graphite.

PTL 1 discloses a graphite structure including a graphite plate with a hole, and a metal covering the entire circumference of the graphite plate including an inner circumference of the hole while preventing the hole from being closed, the metal being likely to react with carbon such as titanium. PTL 1 describes the configuration above that enables solving a problem of delamination between graphite layers due to stress generated when a device or an electronic device, which is equipped with the graphite structure, is heated or cooled.

PTL 2 discloses a method for manufacturing a graphite structure in which a graphite sheet and a pressure-sensitive adhesive are laminated and sliced perpendicularly to a lamination direction to obtain the graphite structure. This graphite structure includes the graphite sheet with a basal surface disposed in a thickness direction, so that thermal conductivity in the thickness direction can be improved.

### CITATION LIST

### Patent Literature

PTL 1: Japanese Patent No. 6008117
PTL 2: Unexamined Japanese Patent Publication No. 2009-295921

### SUMMARY OF THE INVENTION

A graphite structure according to an aspect of the present disclosure includes: a graphite plate including at least one through-hole passing through the graphite plate in a direction orthogonal to a basal surface of the graphite plate; a coating layer covering an inner peripheral surface of the at least one through-hole and an entire circumference of the graphite plate, the coating layer including a first metal capable of forming a compound with carbon atoms constituting the graphite plate; a porous second metal covering an entire circumference of the coating layer including a region surrounded by the inner peripheral surface of the at least one through-hole; and a third metal covering an entire circumference of the porous second metal, the graphite plate and the porous second metal being bonded to each other with the coating layer interposed the graphite plate and the porous second metal, and the third metal being bonded to the porous second metal.

A method for manufacturing a graphite structure according to an aspect of the present disclosure includes the steps of: machining a through-hole in a graphite plate; covering an inner peripheral surface of the through-hole and an entire circumference of the graphite plate with a first metal capable of forming a compound with carbon atoms constituting the graphite plate; covering an entire circumference of a coating layer of the first metal coating the graphite plate with a porous second metal, the coating layer including a region surrounded by the inner peripheral surface of the through-hole; and covering an entire circumference of the porous second metal with a third metal.

### BRIEF DESCRIPTION OF THE DRAWINGS

FIG. 1A is a schematic sectional view illustrating a sectional structure of a graphite structure according to a first exemplary embodiment.

FIG. 1B is a schematic sectional view illustrating a sectional structure of the graphite structure of FIG. 1A as viewed from a Z-Z direction.

FIG. 2 is a flowchart of a method for manufacturing the graphite structure according to the first exemplary embodiment.

FIG. 3 is Table 1 showing manufacturing conditions of graphite structures according to Reference Examples 1 to 5 and Examples 1 to 7 and evaluation results of the obtained graphite structures.

### DESCRIPTION OF EMBODIMENT

Although the configuration of PTL 1 can secure resistance to thermal shock, thermal conductivity in a thickness direction is not improved due to a metal coating layer with a thickness of 0.2 μm or less.

Although the configuration of PTL 2 improves thermal conductivity in a thickness direction in a layer of the graphite sheet, thermal conductivity is lower than that of normal graphite in a direction in which the pressure-sensitive adhesive is laminated because the pressure-sensitive adhesive is disposed.

Thus, it is an object of the present disclosure to provide a graphite structure that achieves both thermal conductivity in a plane direction and thermal conductivity in a thickness direction at a high level.

A graphite structure according to a first aspect of the present disclosure includes: a graphite plate including at least one or more through-holes passing through the graphite plate in a direction orthogonal to a basal surface of the graphite plate; a coating layer covering an inner peripheral surface of the at least one through-hole and an entire circumference of the graphite plate, the coating layer including a first metal capable of forming a compound with carbon atoms constituting the graphite plate; a porous second metal covering an entire circumference of the coating layer including a region surrounded by the inner peripheral surface of the at least one through-hole; and a third metal covering an entire circumference of the porous second metal, the graphite plate and the porous second metal being bonded to each other with the coating layer interposed the graphite plate and the porous second metal, and the third metal being bonded to the porous second metal.

A graphite structure according to a second aspect in the first aspect may be configured such that the at least one through-hole has a total area in a range from 5% to 50% inclusive with respect to an area of the graphite plate, and a maximum area per one through-hole is in a range from 5% to 50% inclusive with respect to the area of the graphite plate.

A graphite structure according to a third aspect in the first aspect may be configured such that the coating layer contains any one of metals of nickel and titanium, or an alloy containing the any one of metals as a main component, as the first metal, the coating layer being formed over the inner peripheral surface of the at least one through-hole and the entire circumference of the graphite plate while having a thickness in a range from 0.01 μm to 20 μm inclusive.

A graphite structure according to a fourth aspect in the first aspect may be configured such that the porous second metal is copper or an alloy containing copper as a main component, and the porous second metal is formed over the entire circumference of the coating layer while having a thickness in a range from 0.01 mm to 0.5 mm inclusive, and a porosity in a range from 5% to 30% inclusive.

A graphite structure according to a fifth aspect in the first aspect may be configured such that the third metal is copper or an alloy containing copper as a main component, and the third metal is formed covering an outer periphery of the porous second metal while having a thickness in a range from 1 μm to 100 μm inclusive and causing an outside from the graphite plate to be formed of the third metal bonded.

A method for manufacturing a graphite structure according to a sixth aspect includes the steps of: machining a through-hole in a graphite plate; covering an inner peripheral surface of the through-hole and an entire circumference of the graphite plate with a first metal capable of forming a compound with carbon atoms constituting the graphite plate; covering an entire circumference of a coating layer of the first metal coating the graphite plate with a porous second metal, the coating layer including a region surrounded by the inner peripheral surface of the through-hole; and covering an entire circumference of the porous second metal with a third metal.

The graphite structure according to the present disclosure causes the porous second metal to form a thermal path in a region (graphite hole) provided with the through-hole in the graphite plate, thereby increasing the thermal conductivity in the thickness direction. Additionally, excellent thermal conductivity in a plane direction of the graphite plate also can be achieved in other regions of the graphite plate. In particular, customized shape processing of a graphite hole is available even for an electric circuit component having a plurality of local heat generation sources, so that heat dissipation measures for various electric circuit components can be improved.

Hereinafter, a graphite structure according to an exemplary embodiment of the present disclosure will be described with reference to the drawings. Each drawing illustrates each element in an exaggerated manner to facilitate description.

### EXEMPLARY EMBODIMENTS

### <Graphite Structure 1>

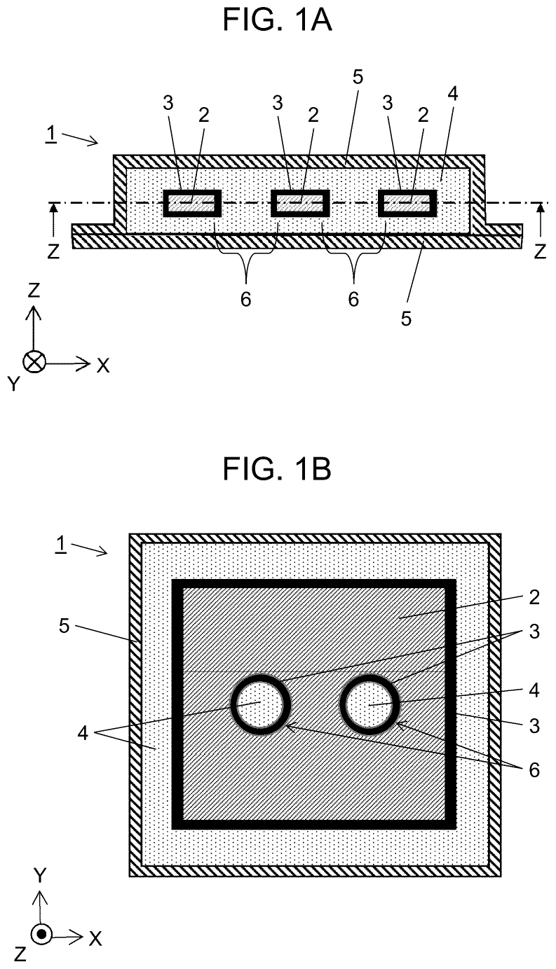

FIG. 1A is a schematic sectional view of graphite structure 1 according to a first exemplary embodiment. FIG. 1B is a schematic sectional view illustrating a sectional structure of the graphite structure of FIG. 1A as viewed from a Z-Z direction. For the sake of convenience, a basal surface of graphite plate 2 is defined as a plane parallel to an XY-plane, and through-hole 6 is open in a direction that is indicated as a Z-direction.

Graphite structure 1 according to the first exemplary embodiment includes graphite plate 2 with through-hole 6, coating layer 3 covering an inner peripheral surface of through-hole 6 and an entire circumference of graphite plate 2 with a first metal, porous second metal 4 covering an entire circumference of coating layer 3, and third metal 5 covering an entire circumference of the porous second metal 4. The first metal is capable of forming a compound with carbon atoms constituting the graphite plate. Porous second metal 4 is used to cover the entire circumference of coating layer 3 including a region surrounded by the inner peripheral surface of through-hole 6. Graphite plate 2 and porous second metal 4 are bonded to each other with coating layer 3 interposed therebetween. Third metal 5 is bonded to porous second metal 4.

The above configuration enables providing a thermally conductive member including graphite plate 2 that is completely incorporated in three kinds of metal (first metal 3, second metal 4, third metal 5).

### <Method for Manufacturing Graphite Structure>

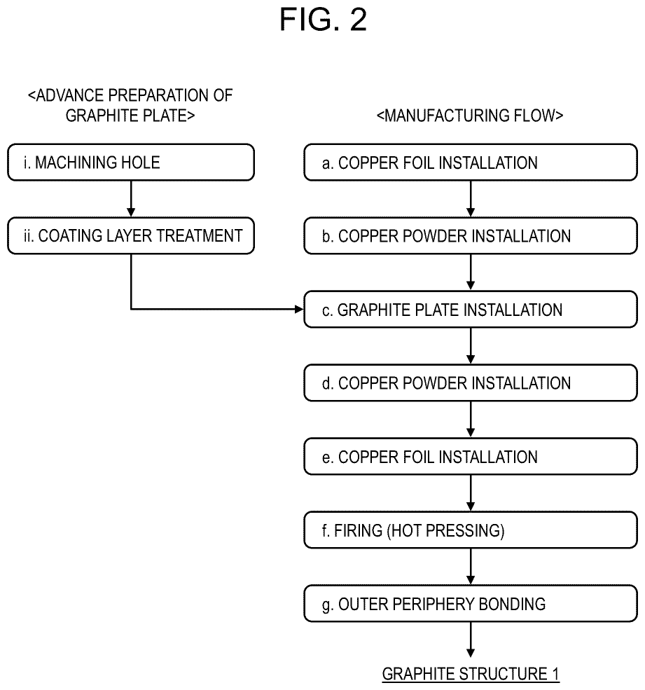

FIG. 2 is a flowchart (steps a to g) of a method for manufacturing the graphite structure according to the first exemplary embodiment.

### <Advance Preparation of Graphite Plate>

(1) First, an arbitrary hole is preliminarily made to pass through graphite plate 2 at a desired position (graphite hole 6) as an advance preparation of graphite plate 2.
(2) Subsequently, the entire circumference of graphite plate 2 including an inner peripheral surface of graphite hole 6 is covered with coating layer 3 made of the first metal described later. At this time, coating layer 3 is formed in a range in which the hole passing through graphite plate 2 is not closed. The hole formed here (an inner diameter of coating layer 3 coating the inner peripheral surface of graphite hole 6) is subjected to application of copper powder in subsequent manufacturing flow d as copper powder installation, and porous metal 4 is formed in manufacturing flow f as firing (hot pressing).

### <Manufacturing Flow>

Step “a”. Copper foil installation: Copper foil with a thickness in a range from 6 μm to 100 μm inclusive is installed. When the thickness is less than 6 μm, problems such as breakage may occur. Conversely, when the thickness exceeds 100 μm, thermal characteristics in the plane direction as a graphite structure may be deteriorated.

Step “b”. Copper powder installation: copper powder or copper alloy powder having a particle size in a range from 1 μm to 200 μm inclusive is installed at a height in a range from 10 μm to 500 μm inclusive on the copper foil installed in step “a” and in a range inside the copper foil installed in step “a”. When the particle size is less than 1 μm, economic efficiency is poor. Conversely, when the thickness exceeds 200 μm, the porosity as a graphite structure may increase to deteriorate thermal characteristics. When the installation height is less than 10 μm, an unnecessary porosity as a graphite structure may increase to deteriorate the thermal characteristics. Conversely, when the installation height exceeds 500 μm, a volume occupancy rate of copper or a copper alloy in the graphite structure may increase to deteriorate the thermal characteristics. Squeezing during the copper powder installation facilitate uniformity of thickness of the graphite structure.

Step “c”. Graphite plate installation: Graphite plate 2 prepared in advance is installed on the copper powder or the copper alloy powder installed in step “b”.

Step “d”. Copper powder installation: copper powder or copper alloy powder is installed on graphite plate 2 installed in step “c” as in step “b”. At this time, the copper powder or the copper alloy powder is embedded in graphite hole 6.

Step “e”. Copper foil installation: Copper foil is installed on the copper powder or the copper alloy powder installed in step “d” as in step “a”.

Step “f”. Firing (hot pressing): The product after completion of step “e” is subjected to hot pressure welding in an inert atmosphere in a range from 1100° C. to 1200° C. inclusive by applying a press pressure in a range from 0.05 kgf/cm² to 1 kgf/cm² inclusive. When the temperature is lower than 1100° C., bonding of the copper powder or the copper alloy powder may not be promoted. Conversely, when the temperature exceeds 1200° C., the copper powder or the copper alloy powder may be completely melted to cause not only graphite plate 2 to be difficult in maintaining its attitude, but also the copper foil on the surface to be thermally decomposed. When the pressing pressure is less than 0.05 kgf/cm², the bonding of the copper powder or the copper alloy powder may not be promoted. Conversely, when the pressing pressure exceeds 1 kgf/cm², the copper foil may be broken. As a result, the copper powder or the copper alloy powder is bonded to form porous second metal 4.

Step “g”. Outer periphery bonding: The copper foil present up and that present down outside the copper foil in step “b” and step “d” are bonded to each other. A bonding method is not particularly limited, and can be selected from laser welding, hot bonding, ultrasonic bonding, solder bonding, and the like. As a result, the copper foil is bonded to form surface metal (third metal) 5.

Through steps “a” to “g” described above, graphite structure 1 is manufactured in which graphite plate 2 and porous metal 4 are bonded to each other with coating layer 3 interposed therebetween, and surface metal 5 is bonded to porous metal 4.

### <Graphite Plate 2>

Graphite plate 2 is crystalline graphite having a size of 50 mm square and a thickness of 0.2 mm. Graphite plate 2 is prepared by heating a polyimide film to 2500° C. or higher in an inert gas atmosphere. Graphite plate 2 desirably has a thermal conductivity of 1200 W/m·K or more in the plane direction, and preferably 1300 W/m·K or more. To form coating layer 3 and porous metal 4 in a subsequent step, a through-hole (graphite hole 6) of Φ4 mm is formed in graphite plate 2 by press working. The through-hole preferably has an aperture ratio in a range from 5% to 50% inclusive with respect to an area of graphite plate 2. Any size, shape, and number of the through-hole can be determined within the scope of specifications of graphite structure 1 to be finally finished. When the aperture ratio is less than 5%, the copper powder or the copper alloy powder may be completely melted to cause graphite plate 2 to be difficult in maintaining its attitude. Conversely, when the aperture ratio exceeds 50%, the thermal characteristics of graphite structure 1 may be deteriorated. Graphite plate 2 may include a plurality of through-holes 6. The plurality of through-holes 6 may be different in area. A maximum area per through-hole is preferably in a range from 5% to 50% inclusive of an area of the graphite plate. The maximum area per through-hole refers to a maximum area among a plurality of different areas.

### <Coating Layer (First Metal) 3>

Coating layer 3 contains any one of metals of nickel and titanium or an alloy containing the metal as a main component, as the first metal. Coating layer 3 is formed over the inner peripheral surface of through-hole 6 and the entire circumference of graphite plate 2. Coating layer 3 has a thickness in a range from 0.01 μm to 20 μm inclusive. A method for forming coating layer 3 can be selected from plating, vapor deposition, sputtering, and the like. When the thickness is less than 0.01 μm, problems such as voids may occur. Conversely, when the thickness exceeds 20 μm, the thermal characteristics as a graphite structure may be deteriorated due to low thermal conductivity of the nickel or the titanium. Then, extreme increase in thickness causes a difficulty in achieving downsizing of a device and an electronic device.

### <Porous Metal (Second Metal) 4>

Porous metal (second metal) 4 is a sintered body formed by hot pressing of copper powder or copper alloy powder. Porous metal 4 is formed over the entire circumference of coating layer 3. Porous metal 4 has a thickness in a range from 10 μm to 500 μm inclusive. Porous metal 4 has a porosity in a range from 5% to 30% inclusive that represents porous properties. When the thickness is less than 10 μm, a particle size of the copper powder in steps “b” and “d” may be limited to cause a difficulty in squeezing. Conversely, when the thickness exceeds 500 μm, the thermal characteristics as a graphite structure may be deteriorated. When the porosity is less than 5%, the copper powder or the copper alloy powder may be completely melted to cause graphite plate 2 to be difficult in maintaining its attitude. Conversely, when the porosity exceeds 30%, the thermal characteristics of graphite structure 1 may be deteriorated.

Although the porous metal (second metal) is here a sintered body formed by hot pressing of copper powder or copper alloy powder, the porous metal (second metal) is not limited thereto. Other porous metals may be used.

### <Surface Metal (Third Metal) 5>

Surface metal (third metal) 5 can be selected from any copper foil having a thickness in a range from 6 μm to 100 μm inclusive. When the thickness is less than 6 μm, problems such as breakage may occur. Conversely, when the thickness exceeds 100 μm, the copper foil may be less likely to be bent to cause a difficulty in bonding around its outer periphery.

Although the copper foil is here described in which the copper foil is bonded as the surface metal (third metal), the surface metal is not limited to the copper foil. Another metal may be used as long as it is capable of covering a surface.

### Examples 1 to 7 and Reference Examples 1 to 5

Graphite structure 1 was produced using graphite plate 2 produced based on the present exemplary embodiment. As a common standard, graphite plate 2 has a size of 50 mm square and a thickness of 0.2 mm. Coating layer 3 is formed by nickel plating, and has a thickness of 10 μm. Porous metal 4 was formed of copper powder having a particle size of less than 180 μm. Surface metal 5 has a size of 70 mm square and a thickness of 0.01 mm. Other standards are described in the following Examples. Hot pressing was performed at a rising and falling temperature rate of 10° C./min and a pressing pressure of 0.1 kgf/cm² under conditions where temperature was maintained for 30 minutes or 60 minutes to stabilize temperature at a set maximum temperature.

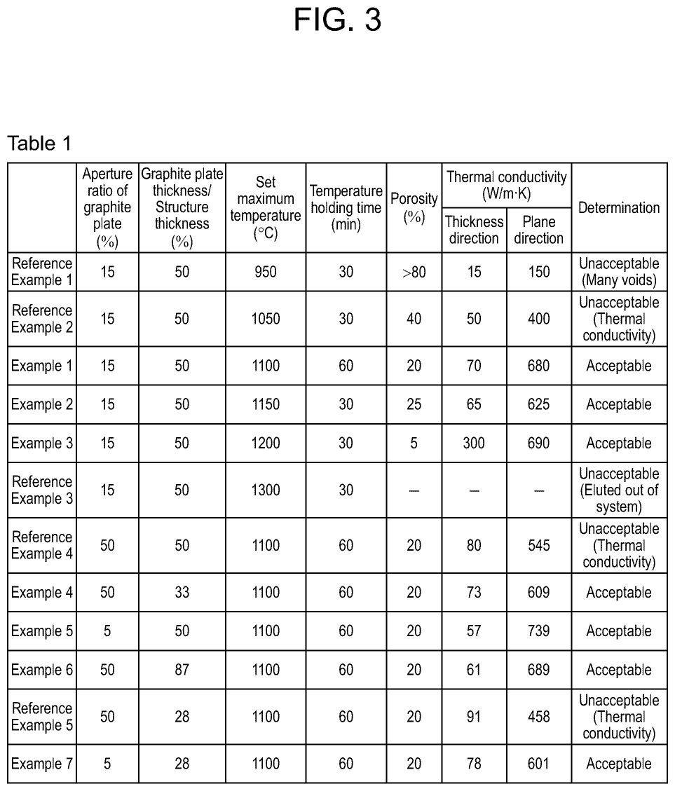

The porosity was calculated from cross-sectional observation of produced graphite structure 1. The thermal conductivity in the thickness direction was measured with a TIM tester (manufactured by ANALYSISTECH). The thermal conductivity in the plane direction was calculated according to a rule of mixture because there is no method for measuring a composite such as graphite structure 1 according to the present disclosure. The results were determined as pass when the thermal conductivity in the thickness direction was 50 W/m·K or more and the thermal conductivity in the plane direction was 600 W/m·K or more. FIG. 3 is Table 1 showing manufacturing conditions of graphite structures according to Reference Examples 1 to 5 and Examples 1 to 7 and evaluation results of the obtained graphite structures.

### Reference Example 1

The hot pressing was performed using the graphite plate having an aperture ratio of 15% of a total area of the graphite plate and a thickness that was 50% of a total thickness of the graphite structure under conditions including a set maximum temperature of 950° C. and a temperature holding time of 30 minutes. Evaluation results of the hot pressing show that the porosity of the porous metal was 80% or more, and the thermal conductivity was also unacceptable.

### Reference Example 2

The hot pressing was performed under conditions including a set maximum temperature of 1050° C. and a temperature holding time of 30 minutes using a member under the same conditions as in Reference Example 1. Results of the hot pressing show that the porosity of the porous metal was about 40%, and the thermal conductivity was also unacceptable.

### Example 1

The hot pressing was performed under conditions including a set maximum temperature of 1100° C. and a temperature holding time of 60 minutes using a member under the same conditions as in Reference Example 1. Evaluation results of the hot pressing show that the porosity of the porous metal was about 20%, and the thermal conductivity was acceptable.

### Example 2

The hot pressing was performed under conditions including a set maximum temperature of 1150° C. and a temperature holding time of 30 minutes using a member under the same conditions as in Reference Example 1. Evaluation results of the hot pressing show that the porosity of the porous metal was about 25%, and the thermal conductivity was acceptable.

### Example 3

The hot pressing was performed under conditions including a set maximum temperature of 1200° C. and a temperature holding time of 30 minutes using a member under the same conditions as in Reference Example 1. Evaluation results of the hot pressing show that the porosity of the porous metal was about 5%, and the thermal conductivity was acceptable.

### Reference Example 3

The hot pressing was performed under conditions including a set maximum temperature of 1300° C. and a temperature holding time of 30 minutes using a member under the same conditions as in Reference Example 1. Evaluation results of the hot pressing show that copper was completely melted and eluted out of a system, and thus are unacceptable.

### Reference Example 4

The hot pressing was performed using the graphite plate having an aperture ratio of 50% of a total area of the graphite plate and a thickness that was 50% of a total thickness of the graphite structure under conditions including a set maximum temperature of 1100° C. and a temperature holding time of 60 minutes. Evaluation results of the hot pressing show that the porosity of the porous metal was about 20%, and only the thermal conductivity in the plane direction was unacceptable. This is because the aperture ratio of graphite increased to deteriorate heat transfer capability in the plane direction.

### Example 4

The hot pressing was performed using the graphite plate having an aperture ratio of 50% of a total area of the graphite plate and a thickness that was 33% of a total thickness of the graphite structure under the same hot pressing conditions as in Reference Example 4. Evaluation results of the hot pressing show that the porosity of the porous metal was about 20%, and the thermal conductivity was acceptable.

### Example 5

The hot pressing was performed using the graphite plate having an aperture ratio of 5% of a total area of the graphite plate and a thickness that was 50% of a total thickness of the graphite structure under the same hot pressing conditions as in Reference Example 4. Evaluation results of the hot pressing show that the porosity of the porous metal was about 20%, and the thermal conductivity was acceptable.

### Example 6

The hot pressing was performed using the graphite plate having an aperture ratio of 50% of a total area of the graphite plate and a thickness that was 87% of a total thickness of the graphite structure under the same hot pressing conditions as in Reference Example 4. Evaluation results of the hot pressing show that the porosity of the porous metal was about 20%, and the thermal conductivity was acceptable.

### Reference Example 5

The hot pressing was performed using the graphite plate having an aperture ratio of 50% of a total area of the graphite plate and a thickness that was 28% of a total thickness of the graphite structure under the same hot pressing conditions as in Reference Example 4. Evaluation results of the hot pressing show that the porosity of the porous metal was about 20%, and only the thermal conductivity in the plane direction was unacceptable. This is because a ratio of the graphite plate decreased to deteriorate heat transfer capability in the plane direction.

### Example 7

The hot pressing was performed using the graphite plate having an aperture ratio of 5% of a total area of the graphite plate and a thickness that was 28% of a total thickness of the graphite structure under the same hot pressing conditions as in Reference Example 4. Evaluation results of the hot pressing show that the porosity of the porous metal was about 20%, and the thermal conductivity was acceptable.

### Effects

The configuration of the present exemplary embodiment provides a graphite structure with not only thermal conductivity in the plane direction that is 1.5 times or more larger than that of pure copper, but also thermal conductivity in the thickness direction that has increased as in metal. The configuration also enables bonding in a solid phase, and thus facilitating positioning of built-in graphite to be available for a spot heat source.

### INDUSTRIAL APPLICABILITY

The graphite structure according to the present disclosure is excellent in thermal conductivity in both the plane direction and the thickness direction, and thus is applicable to the fields of semiconductor devices, in-vehicle devices, electronic devices, and the like having local heat sources, and is industrially useful.

### REFERENCE MARKS IN THE DRAWINGS

1 graphite structure
2 graphite plate
3 coating layer
4 porous second metal
5 third metal
6 graphite hole

1. A graphite structure comprising:
a graphite plate including at least one through-hole passing through the graphite plate in a direction orthogonal to a basal surface of the graphite plate;
a coating layer covering an inner peripheral surface of the at least one through-hole and an entire circumference of the graphite plate, the coating layer including a first metal capable of forming a compound with carbon atoms constituting the graphite plate;
a porous second metal covering an entire circumference of the coating layer including a region surrounded by the inner peripheral surface of the at least one through-hole; and
a third metal covering an entire circumference of the porous second metal,
the graphite plate and the porous second metal being bonded to each other with the coating layer interposed between the graphite plate and the porous second metal, and
the third metal being bonded to the porous second metal.

2. The graphite structure according to claim 1, wherein the at least one through-hole has a total area in a range from 5% to 50% inclusive with respect to an area of the graphite plate, and a maximum area per one through-hole is in a range from 5% to 50% inclusive with respect to the area of the graphite plate.

3. The graphite structure according to claim 1, wherein the coating layer contains any one of metals of nickel and titanium, or an alloy containing the any one of metals as a main component, as the first metal, the coating layer being formed over the inner peripheral surface of the at least one through-hole and the entire circumference of the graphite plate while having a thickness in a range from 0.01 μm to 20 μm inclusive.

4. The graphite structure according to claim 1, wherein the porous second metal is copper or an alloy containing copper as a main component, and the porous second metal is formed over the entire circumference of the coating layer while having a thickness in a range from 0.01 mm to 0.5 mm inclusive, and a porosity in a range from 5% to 30% inclusive.

5. The graphite structure according to claim 1, wherein the third metal is copper or an alloy containing copper as a main component, and the third metal is formed covering an outer periphery of the porous second metal while having a thickness in a range from 1 μm to 100 μm inclusive and causing an outside from the graphite plate to be formed of the third metal bonded.

6. A method for manufacturing a graphite structure, the method comprising the steps of:
machining a through-hole in a graphite plate;
covering an inner peripheral surface of the through-hole and an entire circumference of the graphite plate with a first metal capable of forming a compound with carbon atoms constituting the graphite plate;
covering an entire circumference of a coating layer of the first metal coating the graphite plate with a porous second metal, the coating layer including a region surrounded by the inner peripheral surface of the through-hole; and
covering an entire circumference of the porous second metal with a third metal.
